(19) United States
(12) Patent Application Publication
(10) Pub. No.: US 2015/0181721 A1
(43) Pub. Date: Jun. 25, 2015

(54) COMPONENT MOUNTING METHOD AND MOUNTING COMPONENT

(71) Applicants: FUJITSU LIMITED, Kawasaki-shi (JP); FUJITSU TELECOM NETWORKS LIMITED, Kawasaki-shi (JP)

(72) Inventors: Junichi HAYAMA, Kawasaki (JP); Kenji Tsutsumi, Kawasaki (JP); Takashi Inoue, Hanyu (JP); Hiroyuki Shouyama, Fukuoka (JP); Makoto Hirano, Kawasaki (JP); Kenji Ishikawa, Kawasaki (JP)

(73) Assignees: FUJITSU LIMITED, Kawasaki-shi (JP); FUJITSU TELECOM NETWORKS LIMITED, Kawasaki-shi (JP)

(21) Appl. No.: 14/552,620

(22) Filed: Nov. 25, 2014

(30) Foreign Application Priority Data
Dec. 20, 2013 (JP) 2013-264539

(51) Int. Cl. H05K 3/30

(52) U.S. Cl. CPC H05K 3/301

(57) ABSTRACT

A component mounting method includes: placing a mounting component in contact with, and on top of, an electronic component on a substrate, pressing a spring member against the mounting component using a jig such that the mounting component is pushed against the electronic component by the spring member, and fixing the spring member to the substrate, and removing the jig in a direction heading away from a mounting face of the substrate after the spring member has been fixed to the substrate.

### CROSS-REFERENCE TO RELATED APPLICATION

This application is based upon and claims the benefit of priority of the prior Japanese Patent Application No. 2013-264539, filed on Dec. 20, 2013, the entire contents of which are incorporated herein by reference.

### FIELD

The embodiments discussed herein are related to a component mounting method, and a mounting component.

### BACKGROUND

In a known structure, a guide member including a frame portion and a support column portion is fixed to a printed circuit board, a heat sink is placed at the inner periphery of the guide member so as to make close contact with an integrated circuit package, and a cover covering an outer peripheral edge portion of an upper face of the heat sink is fixed to the guide member. In another known structure, plural power devices are mounted on an insulating sheet on a radiation fin, and a pressing member is screw-fixed to the radiation fin such that a tab of the pressing member presses down the power devices.

### RELATED PATENT DOCUMENTS

Japanese Laid-Open Patent Publication No. 7-130924

Japanese Laid-Open Patent Publication No. 6-342989

### SUMMARY

According to an aspect of the embodiments, a component mounting method includes: placing a mounting component in contact with, and on top of, an electronic component on a substrate; pressing a spring member against the mounting component using a jig such that the mounting component is pushed against the electronic component by the spring member, and fixing the spring member to the substrate; and removing the jig in a direction heading away from a mounting face of the substrate after the spring member has been fixed to the substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a side view illustrating a state partway through a component mounting method of a first exemplary embodiment.

FIG. 2 is a perspective view illustrating a substrate, an integrated circuit, a spring member, a radiating member, and a jig in a component mounting method of the first exemplary embodiment.

FIG. 3A is a side view illustrating a state partway through a component mounting method of the first exemplary embodiment.

FIG. 3B is a partially cut-away side view illustrating a state partway through a component mounting method of the first exemplary embodiment.

FIG. 3C is a partially cut-away side view illustrating a state partway through a component mounting method of the first exemplary embodiment.

FIG. 3D is a partially cut-away side view illustrating a state partway through a component mounting method of the first exemplary embodiment.

FIG. 3E is a partially cut-away side view illustrating a state partway through a component mounting method of the first exemplary embodiment.

FIG. 3F is a side view illustrating a state partway through a component mounting method of the first exemplary embodiment.

FIG. 4 is a side view illustrating a state partway through a component mounting method of a first comparative example.

FIG. 5 is a side view illustrating a state partway through a component mounting method of a second comparative example.

FIG. 6 is a partially cut-away side view illustrating a state partway through a component mounting method of a second exemplary embodiment.

FIG. 7A is a side view illustrating a state partway through a component mounting method of the second exemplary embodiment.

FIG. 7B is a cutaway side view illustrating a state partway through a component mounting method of the second exemplary embodiment.

FIG. 7C is a partially cutaway side view illustrating a state partway through a component mounting method of the second exemplary embodiment.

FIG. 7D is a partially cutaway side view illustrating a state partway through a component mounting method of the second exemplary embodiment.

FIG. 7E is a partially cutaway side view illustrating a state partway through a component mounting method of the second exemplary embodiment.

FIG. 7F is a partially cutaway side view illustrating a state partway through a component mounting method of the second exemplary embodiment.

FIG. 8A is a plan view illustrating a fitted state of a spring member to a radiating member in a component mounting method of a third exemplary embodiment.

FIG. 8B is a plan view illustrating a state prior to fitting a spring member to a radiating member in a component mounting method of a third exemplary embodiment.

FIG. 9 is a perspective view illustrating a radiating member and a jig in a component mounting method of a fourth exemplary embodiment.

FIG. 10A is a cross-section illustrating a press pin and a through hole in a component mounting method of the fourth exemplary embodiment.

FIG. 10B is a cross-section illustrating a press pin and a through hole in a component mounting method of the fourth exemplary embodiment.

FIG. 10C is a cross-section illustrating a press pin and a through hole in a component mounting method of the fourth exemplary embodiment.

### DESCRIPTION OF EMBODIMENTS

Detailed explanation follows regarding a first exemplary embodiment, with reference to the drawings.

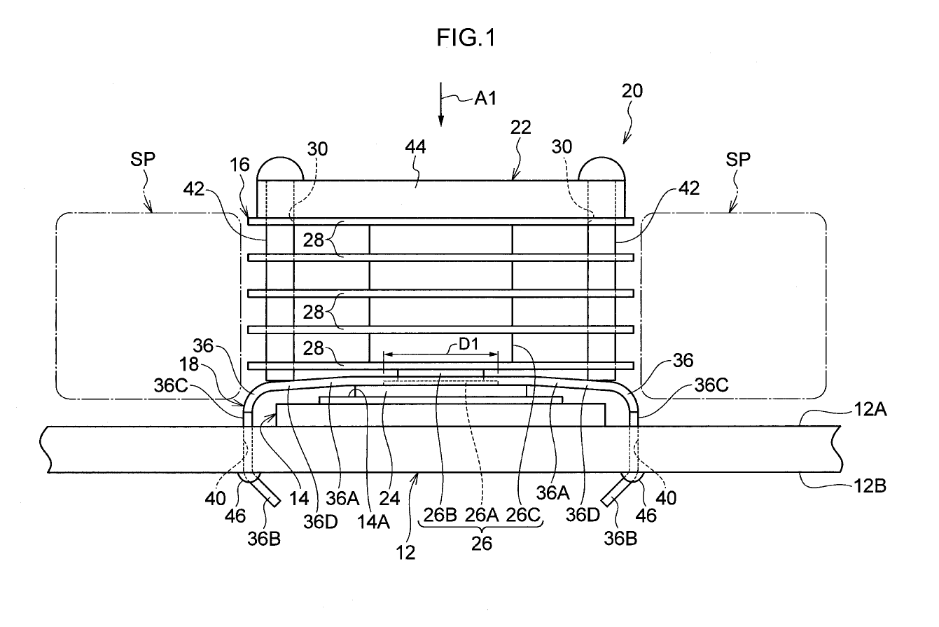

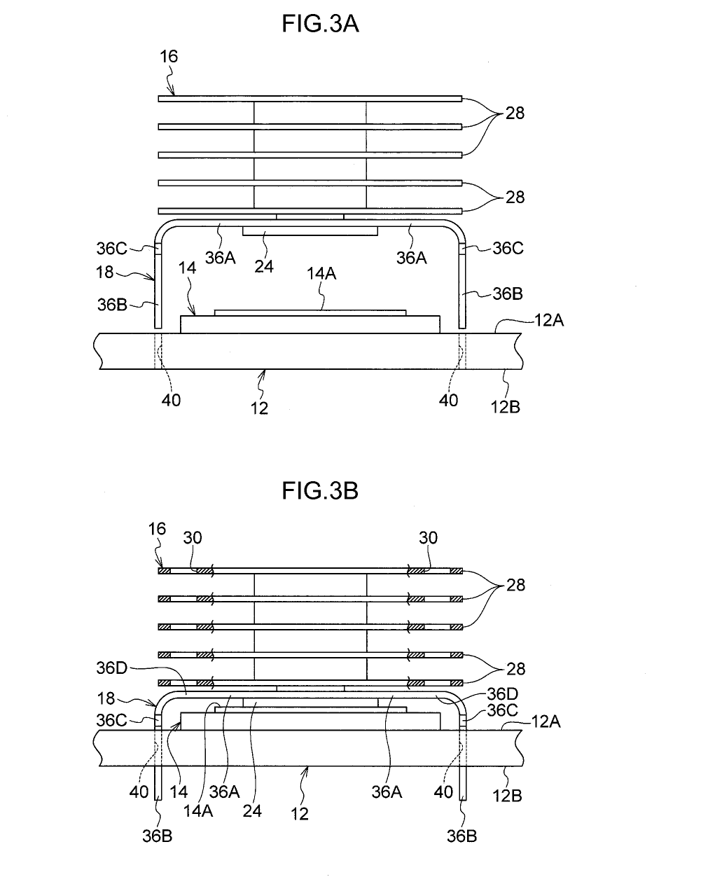

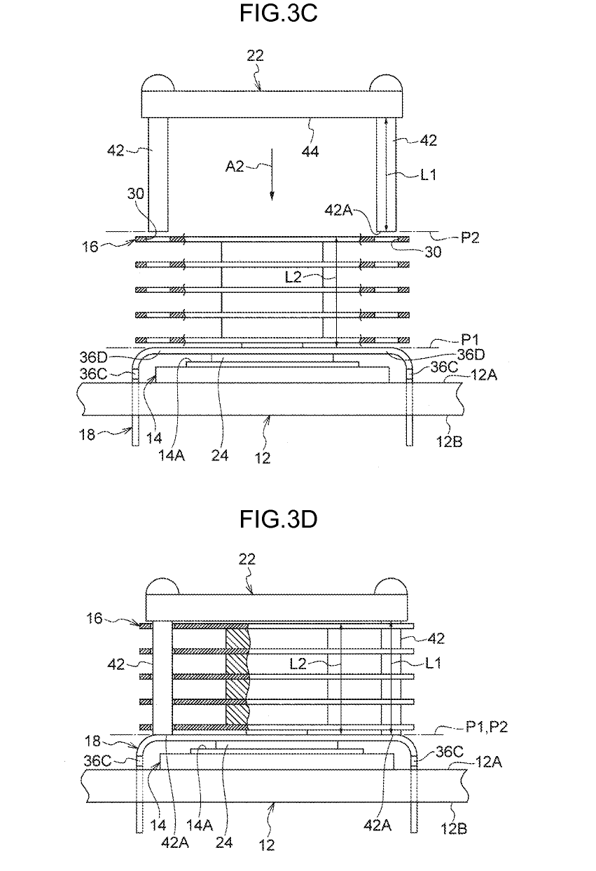

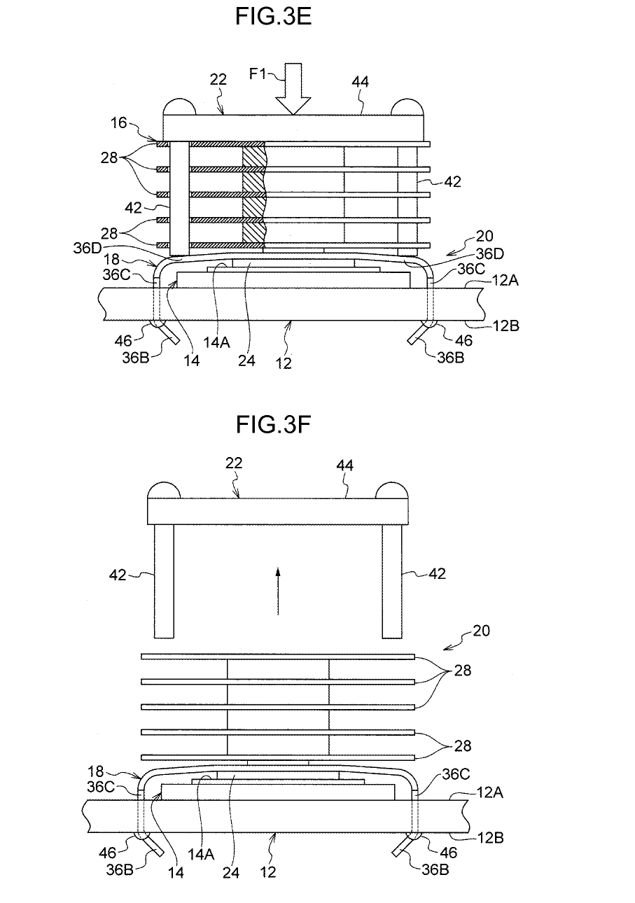

FIG. 1 illustrates a state partway through mounting an integrated circuit 14 and a radiating member 16 onto a substrate 12 in a component mounting method of the first exemplary embodiment. FIG. 3A to FIG. 3F illustrate in sequence the component mounting method of the first exemplary embodiment.

In the first exemplary embodiment, the integrated circuit 14 is mounted onto a mounting face 12A of the substrate 12. The radiating member 16 is mounted over an upper face 14A of the integrated circuit 14. The radiating member 16 is pushed toward the substrate 12 by a spring member 18. The mounting face 12A is an upper face of the substrate 12 in the example illustrated in FIG. 1.

In the present exemplary embodiment, a circuit board 20 includes various members such as the substrate 12, the integrated circuit 14 installed on the substrate 12, the radiating member 16, and the spring member 18. In other words, the integrated circuit 14, the radiating member 16, and the spring member 18 are all examples of components of the circuit board 20 in the present exemplary embodiment. The integrated circuit 14 is an example of an electronic component, and the radiating member 16 is an example of a mounting component.

Note that FIG. 1 to FIG. 3F illustrate an example in which the integrated circuit 14 is installed to the upper side of the substrate 12, and the radiating member 16 is installed to the upper side of the integrated circuit 14. For convenience, in the following explanation, “up” and “down” refer to “up” and “down” as illustrated in FIG. 1 to FIG. 3E

In the following explanation, “mounting face side” refers to the upper side in FIG. 1. For example, viewing from the mounting face 12A side corresponds to viewing along the arrow A1 direction. Reference to the direction heading away from the 12A corresponds to the opposite direction to the arrow A1 direction. Note that as long as the integrated circuit 14 and the radiating member 16 are mounted to the substrate 12 in this sequence, the integrated circuit 14 and the radiating member 16 need not have the top-bottom positional relationship illustrated in FIG. 1 to FIG. 3E. For example, a lower face of the substrate 12 may configure the mounting face, with the integrated circuit 14 mounted to this mounting face, and the radiating member 16 placed in contact with the lower face of the integrated circuit 14.

As illustrated in FIG. 1, the radiating member 16 includes a contact portion 24 that contacts the upper face 14A of the integrated circuit 14. In the present exemplary embodiment, the contact portion 24 is formed in a circular plate shape.

A support column 26 extends from the contact portion 24 toward the opposite side to the integrated circuit 14. The support column 26 includes a seat portion 26A contiguous to the contact portion 24, a locally narrowed narrow portion 26B extending from the seat portion 26A toward the opposite side to the integrated circuit 14, and a support column main body portion 26C with a smaller diameter than the seat portion 26A extending from the narrow portion 26B.

One, or plural (5 in the example illustrated in FIG. 1 to FIG. 3F) radiating portions 28 extend from the support column main body portion 26C. The radiating portions 28 are an example of a main body portion of the radiating member 16.

In the present exemplary embodiment, the radiating portions 28 extend out in a direction orthogonal to the length direction of the support column main body portion 26C. In particular, in the present exemplary embodiment, the plural radiating portions 28 are formed at regular intervals in the length direction of the support column 26. The contact portion 24 of the radiating member 16 receives heat from the integrated circuit 14. This heat is transmitted from the support column 26 to the radiating portions 28, and externally radiated.

The radiating portions 28 are formed with through holes 30 penetrating in the thickness direction. As viewed along the arrow A1 direction, the radiating member 16 is formed with the through holes 30 at positions corresponding one-to-one with plural respective press pins 42 of a jig 22, described later, through the overall radiating member 16. The positions of the through holes 30 are positions where respective fixing portions 36 of the spring member 18, described later, can be partially seen from the mounting face 12A side of the substrate 12 (as viewed along the arrow A1 direction).

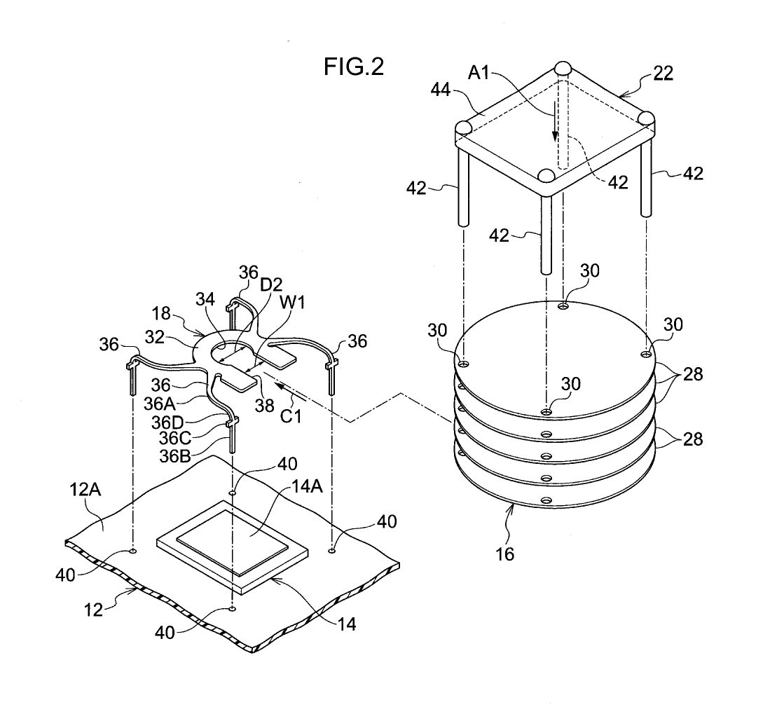

The spring member 18 is fitted to the radiating member 16. As illustrated in FIG. 2, the spring member 18 includes a fitting portion 32 that is fitted to the support column 26 of the radiating member 16. The spring member 18 includes a housing hole 34 at the center of the fitting portion 32. The housing hole 34 has an internal diameter D2 that is slightly larger than the external diameter D1 of the seat portion 26A of the support column 26 (see FIG. 1).

The spring member 18 moreover includes an opening portion 38. The opening portion 38 has an internal width W1 that is slightly narrower than the external diameter D1 of the seat portion 26A, and is in communication with the housing hole 34. The opening portion 38 opens from the housing hole 34 to the outside of the fitting portion 32. The seat portion 26A is housed inside the housing hole 34 through the opening portion 38 (the fitting portion 32 deforms slightly), thereby holding the seat portion 26A in the housing hole 34. The spring member 18 is fitted to the radiating member 16 by holding the seat portion 26A in the housing hole 34.

One or plural (4 in the example illustrated in FIG. 2) of the fixing portions 36 extend out from the fitting portion 32 of the spring member 18. The plural fixing portions 36 extend out from the fitting portion 32 in radiating directions (directions forming angles of substantially 90 degrees to one another in the example illustrated in FIG. 2).

Each of the fixing portions 36 includes a base portion 36A that is substantially parallel to the substrate 12, and an insertion portion 36B that bends toward the substrate 12 side at a leading end side of the base portion 36A. As illustrated in FIG. 1, each of the insertion portions 36B is inserted into a fixing hole 40 formed to the substrate 12, with a leading end side of the insertion portion 36B projecting out at a lower face of the substrate 12. Each insertion portion 36B is formed with a stopper 36C that limits the insertion length into the fixing hole 40 to within a specific range.

In the present exemplary embodiment, as illustrated in FIG. 3C, in the base portions 36A of the plural fixing portions 36, pressed portions 36D that are pressed by the press pins 42 of the jig 22 are positioned within a single flat plane P1. Specifically, in the example illustrated in FIG. 3, the flat plane P1 is a flat plane parallel to the mounting face 12A of the substrate 12.

When fitting the spring member 18 to the substrate 12, the jig 22 presses the spring member 18 from the mounting face 12A side of the substrate 12 (in the arrow A1 direction). The pressed spring member 18 pushes the contact portion 24 of the radiating member 16 toward the integrated circuit 14.

As illustrated in FIG. 1, a leading end side of each of the fixing portions 36 of the spring member 18 is bent around at a back face 12B side of the substrate 12 in the inserted state of the spring member 18 into the fixing holes 40 of the substrate 12, preventing the fixing portions 36 from being pulled out. The leading end sides of the fixing portions 36 are fixed to the back face 12B of the substrate 12 by solder 46 (or by an adhesive).

The jig 22 includes the same number of the press pins 42 as the number of the fixing portions 36 of the spring member 18. The press pins 42 run parallel to each other. The jig 22 includes a coupling plate 44 coupling together the plural press pins 42. In the example illustrated in FIG. 2, the coupling plate 44 is formed in a square plate shape as viewed along the arrow A1 direction. The press pins 42 are fixed in the vicinity of the four corners of the coupling plate 44, and are orthogonal to the coupling plate 44.

The positions of the respective press pins 42 correspond to the positions of the fixing portions 36 of the spring member 18 as viewed along the arrow A1 direction. The positions of the respective press pins 42 moreover correspond to the positions of the through holes 30 as viewed along the arrow A1 direction.

As can be seen in FIG. 3C and FIG. 3D, the length L1 of the press pins 42 is the same or greater than a length L2 from the fixing portions 36 of the spring member 18 to an upper end of the radiating member 16.

In the present exemplary embodiment, the respective press pins 42 are the same length as each other. Leading ends 42A of the respective press pins 42 are accordingly positioned within a single flat plane P2 running parallel to the coupling plate 44.

Explanation follows regarding a component mounting method of the first exemplary embodiment.

As illustrated in FIG. 3A, the integrated circuit 14 is mounted to the mounting face 12A of the substrate 12. In the present exemplary embodiment, the spring member 18 is fitted to the radiating member 16. Specifically, as illustrated by the arrow C1 in FIG. 2, the seat portion 26A of the support column 26 of the radiating member 16 is slotted into the opening portion 38 of the spring member 18. Since the internal width W1 of the opening portion 38 is slightly narrower than the external diameter D1 of the seat portion 26A (see FIG. 1), resistance arises during slotting in. The fitting portion 32 undergoes slight deformation as the seat portion 26A is being slotted into the opening portion 38.

When the seat portion 26A reaches the housing hole 34, the deformation of the fitting portion 32 is released. Since the internal diameter D2 of the housing hole 34 is larger than the external diameter D1 of the seat portion 26A, the seat portion 26A is suppressed from coming out from the housing hole 34.

Next, as illustrated in FIG. 3B, the fixing portions 36 of the spring member 18 are inserted into the fixing holes 40 of the substrate 12, and the contact portion 24 of the radiating member 16 contacts the upper face 14A of the integrated circuit 14. Prior to this stage, the rotation angle of the radiating member 16 is adjusted such that portions (the pressed portions 36D) of the fixing portions 36 of the spring member 18 can be seen through the through holes 30 along the arrow A1 direction.

In this state, as illustrated in FIG. 3C and FIG. 3D, the jig 22 pushes the fixing portions 36 toward the substrate 12 from the mounting face 12A side of the substrate 12.

Specifically, as illustrated by the arrow A2 in FIG. 3C, the respective press pins 42 of the jig 22 are inserted through the through holes 30 of the radiating portions 28 from the opposite side to the substrate 12. As illustrated in FIG. 3D, in the present exemplary embodiment the leading ends 42A of the press pins 42 inserted through the through holes 30 of the radiating portions 28 contact the pressed portions 36D of the fixing portions 36 of the spring member 18.

When this is performed, as illustrated in FIG. 3E, a force F1 is applied to the jig 22 in the arrow A2 direction, and the jig 22 presses the pressed portions 36D of the spring member 18. The spring member 18 pushes the contact portion 24 of the radiating member 16 against the upper face 14A of the integrated circuit 14. When this occurs, the fixing portions 36 may flex (the fixing portions 36 are illustrated in a flexed state in FIG. 3E).

As illustrated in FIG. 3C and FIG. 3D, in the present exemplary embodiment the fixing portions 36 (pressed portions 36D) are positioned within the single flat plane P1 running parallel to the mounting face 12A of the substrate 12. The leading ends 42A of the press pins 42 are positioned within the single flat plane P2 running parallel to the coupling plate 44. The flat plane P2 is thereby maintained in a parallel state to the flat plane P1, and the leading ends 42A of the press pins 42 press the fixing portions 36, thereby enabling the single jig 22 to press all the plural fixing portions 36 at the same time.

In the pressed state of the fixing portions 36 of the spring member 18 by the jig 22, leading end portions of the insertion portions 36B of the spring member 18 are bent around at the lower face side of the substrate 12, and are fixed to the back face 12B of the substrate 12 by solder (or by adhesive). Note that the insertion portions 36B may also be fixed to the substrate 12 simply by bending around the leading end sides of the insertion portions 36B, or simply by adhering the leading end sides of the insertion portions 36B to the substrate by solder or the like.

Fixing the insertion portions 36B to the substrate 12 maintains a state in which the spring member 18 is pushing the radiating member 16 toward the integrated circuit 14.

The jig 22 is then pulled out to the opposite side to the substrate 12, namely in a direction heading away from the mounting face 12A, releasing the pressing of the fixing portions 36 by the jig 22. Fixing the spring member 18 to the substrate 12 maintains a state in which the radiating member 16 above the integrated circuit 14 is pushed against the integrated circuit 14 by the spring member 18, as illustrated in FIG. 3E

In the present exemplary embodiment, as described above, when pressing the spring member 18 with the jig 22, the spring member 18 is pressed in a direction approaching the integrated circuit 14 at the mounting face 12A side of the substrate 12 (the arrow A1 direction). When the pressing of the spring member 18 by the jig 22 is released, the jig 22 is moved in a direction heading away from the mounting face 12A of the substrate 12 (the opposite direction to the arrow A1).

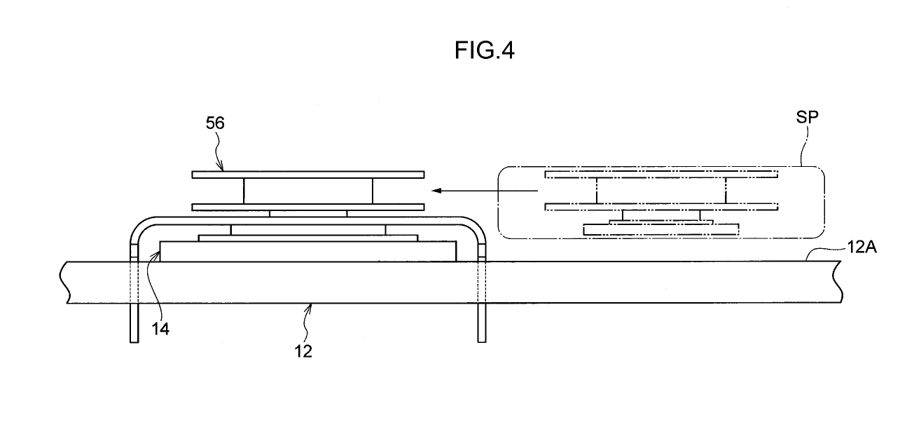

FIG. 4 illustrates a state partway through mounting a radiating member 56 over an integrated circuit 14 on a mounting face 12A of a substrate 12 in a component mounting method of a first comparative example. The first comparative example does not employ the jig 22 of the first exemplary embodiment. The radiating member 56 is fitted to a spring member 18 by sliding the radiating member 56 in the arrow A3 direction from a side position SP, in a state in which the integrated circuit 14 is pushed against the substrate 12 by the spring member 18. Namely, in the first comparative example, the side position SP of the radiating member 56 is employed as a space for sliding the radiating member 56. It is therefore difficult to mount other members (for example other electronic components mounted to the substrate 12, or members such as spacers) at the side position SP of the radiating member 56.

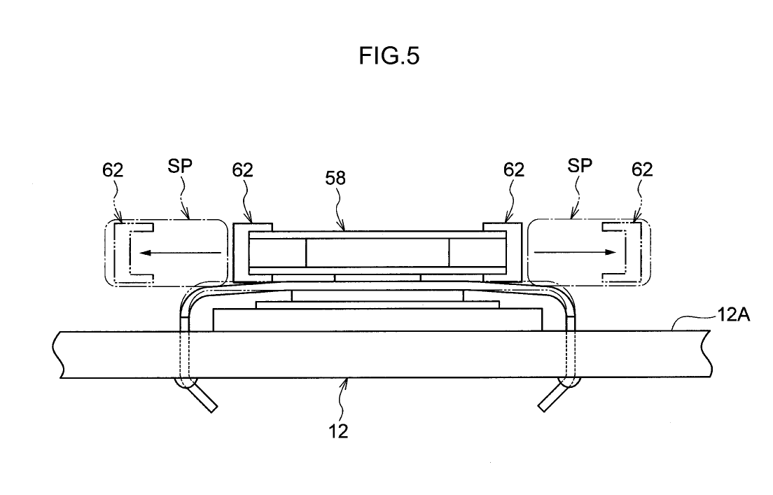

FIG. 5 illustrates a state partway through mounting a radiating member 58 over an integrated circuit 14 on a mounting face 12A of a substrate 12 in a component mounting method of a second comparative example. In the second comparative example, jigs 62 are employed in place of the jig 22 of the first exemplary embodiment. In the second comparative example, the jigs 62 are fitted to the radiating member 58 the radiating member 58 is pushed against the integrated circuit 14 by a spring member 18. After the spring member 18 has been fixed to the substrate 12, the jigs 62 are pulled out in sideways directions. Namely, in the second comparative example side positions SP of the radiating member 58 are employed as spaces for pulling out the jigs 62. It is therefore difficult to mount other members (for example other electronic components mounted to the substrate 12, or members such as spacers) at the side positions SP of the radiating member 58.

By contrast, in the component mounting method of the first exemplary embodiment, when pressing, and releasing the pressing of, the spring member 18 with the jig 22, the jig 22 is moved at the mounting face 12A side of the substrate 12 with respect to the integrated circuit 14. The radiating member 16 and the jig 22 are not moved at side positions SP of the radiating member 16, and the side positions SP are not employed as operation space in the mounting operation, making it possible to place other members at the side positions SP of the radiating member 16. The mounting operation of the radiating member 16 to the substrate 12 can also be simplified.

Placing other members at the side positions SP of the radiating member 16 enables a larger component mounting region to be secured on the substrate 12, enabling more components to be mounted on the substrate 12 than in the first comparative example and the second comparative example. Mounting more components on the substrate 12 allows a contribution to be made to the component mounting density of the substrate 12.

Moreover, since the press pins 42 of the jig 22 are inserted into each of the through holes 30 of the radiating member 16, and the jig 22 simply presses the spring member 18 (fixing portions 36), high dimensional precision is not demanded of the jig 22. Since high dimensional precision is not demanded of the jig 22, the time and cost involved in manufacturing the jig 22 can be reduced.

Next, explanation follows regarding a component mounting method of a second exemplary embodiment. In the second exemplary embodiment, elements, members and so on similar to those of the first exemplary embodiment are allocated the same reference numerals, and detailed explanation thereof is omitted.

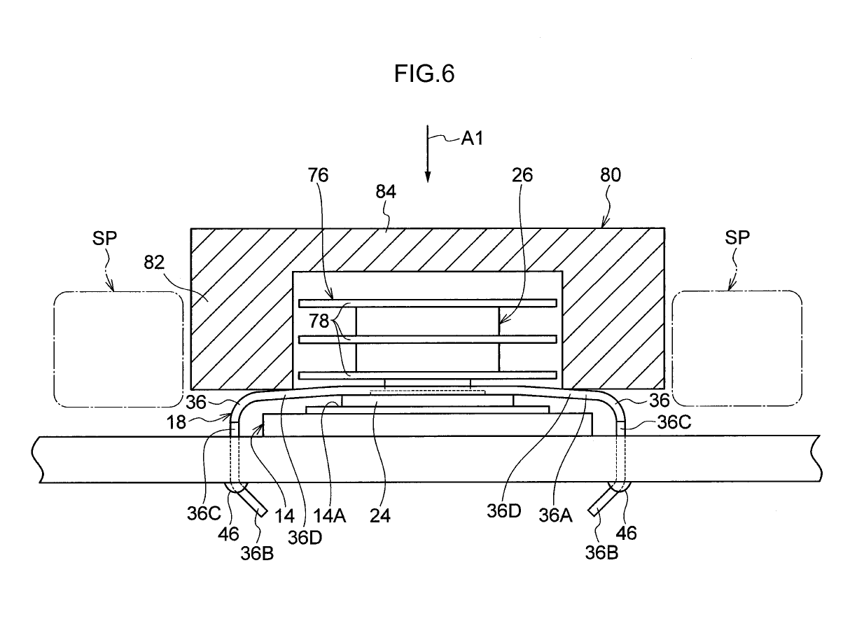

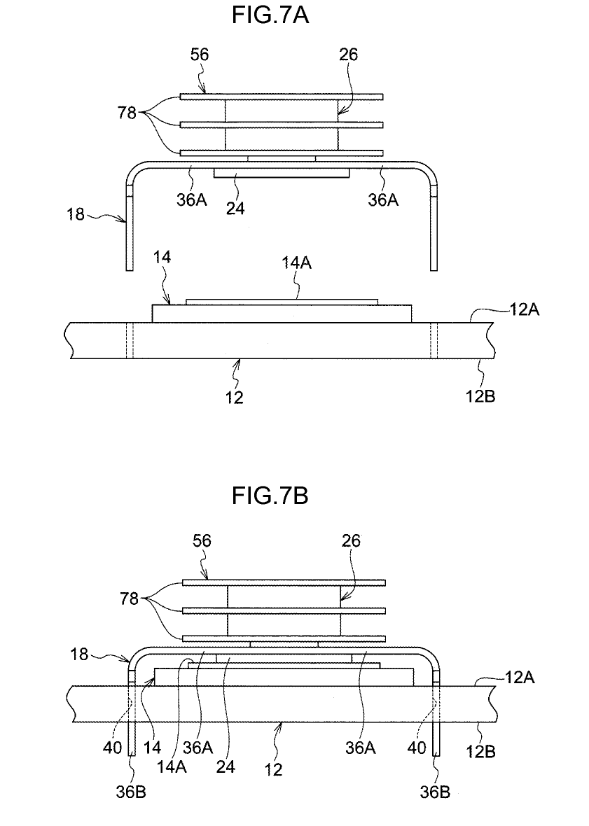

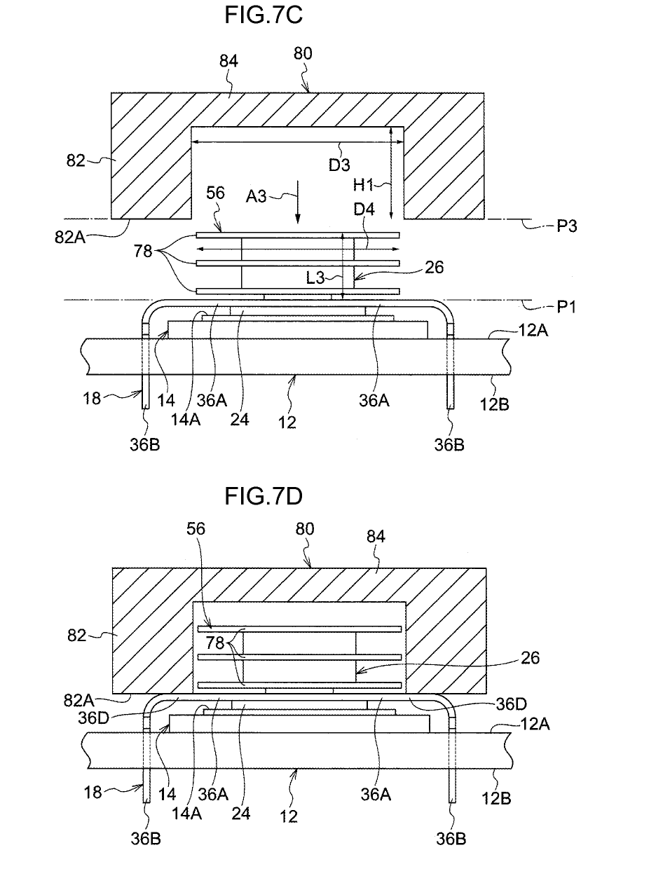

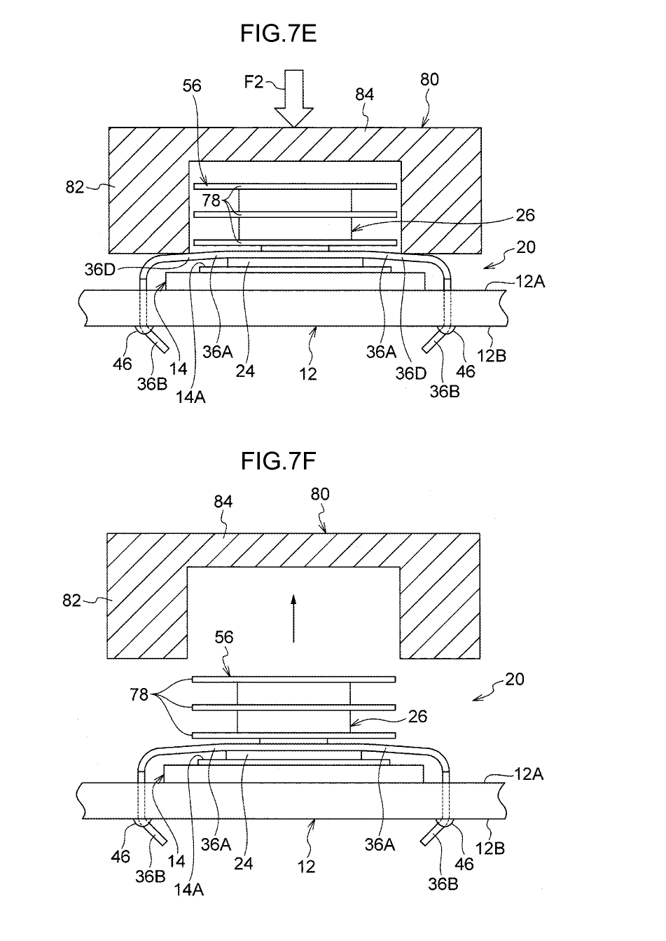

FIG. 6 to FIG. 7F illustrate a component mounting method of the second exemplary embodiment. As viewed along the arrow A1 direction, radiating portions 78 of a radiating member 76 of the second exemplary embodiment are smaller (have a smaller diameter) than the radiating portions 28 of the radiating member 16 of the first exemplary embodiment (see FIG. 1). Accordingly, as viewed along the arrow A1 direction, leading end portions of the fixing portions 36 of the spring member 18 jut out to the outside of the radiating portions 78. In the second exemplary embodiment, there is moreover no need to form the through holes 30 of the first exemplary embodiment (see FIG. 2) in the radiating portions 78. However, the radiating portions 78 may be formed with through holes 30.

A jig 80 of the second exemplary embodiment includes a circular cylinder shaped pressing portion 82, and a bottom portion 84 covering one bottom portion (the upper bottom portion in FIG. 6) of the pressing portion 82. As illustrated in FIG. 7C, an internal diameter D3 of the pressing portion 82 is larger than an external diameter D4 of the radiating portions 78. A height Hl of the pressing portion 82 inside the jig 80 is longer than a length L3 from the fixing portions 36 of the spring member 18 to the upper end of the radiating member 76. A leading end 82A of the pressing portion 82 is positioned within a single flat plane P3 running parallel to the bottom portion 84.

As illustrated in FIG. 7A, similarly to the component mounting method of the first exemplary embodiment, in the component mounting method of the second exemplary embodiment the integrated circuit 14 is mounted to the mounting face 12A of the substrate 12. Likewise, in the second exemplary embodiment, the spring member 18 is fitted to the radiating member 76.

Moreover, as illustrated in FIG. 7B, the contact portion 24 of the radiating member 76 fitted to the spring member 18 is placed in contact with an upper face of the integrated circuit 14 mounted to the substrate 12. When this is performed, the fixing portions 36 of the spring member 18 are inserted into the fixing holes 40 of the substrate 12.

Next, as illustrated in FIG. 7C and FIG. 7D, the jig 80 is used to push the fixing portions 36 (the portions thereof jutting out from the radiating portions 78) toward the substrate 12 from the mounting face 12A side of the substrate 12.

Specifically, as illustrated by the arrow A3 in FIG. 7C, the jig 80 is fitted so as to cover the radiating member 76. Then, as illustrated in FIG. 7D, the leading end 82A of the pressing portion 82 is placed in contact with the fixing portions 36 of the spring member 18.

Here, as illustrated in FIG. 7E, a force F2 in the arrow A3 direction is applied to the jig 80, and the jig 80 presses the pressed portion 36D of the spring member 18. The spring member 18 pushes the contact portion 24 of the radiating member 76 against the upper face 14A of the integrated circuit 14. The fixing portions 36 may flex when this is performed (FIG. 7E illustrates the fixing portions 36 in a flexed state).

In the present exemplary embodiment, the fixing portions 36 are positioned within the single flat plane P1 running parallel to the substrate 12, and the leading end 82A of the pressing portion 82 is positioned in the single flat plane P3 running parallel to the bottom portion 84. Accordingly, by pressing the fixing portions 36 with the leading end 82A of the pressing portion 82 while maintaining the bottom portion 84 in an orientation parallel to the substrate 12, the single jig 80 is capable of pressing all the plural fixing portions 36 at the same time.

In the pressed state of the fixing portions 36 of the spring member 18 by the jig 80, leading end portions of the insertion portions 36B of the spring member 18 are fixed to the substrate 12 by bending and using solder (or an adhesive). Due to fixing the insertion portion 36B to the substrate 12, the spring member 18 maintains the radiating member 76 in a state pushed toward the integrated circuit 14.

The jig 80 is then moved in a direction heading away from the mounting face 12A of the substrate 12. Since the spring member 18 is fixed to the substrate 12, as illustrated in FIG. 7F, the radiating member 76 over the integrated circuit 14 is maintained in a state pushed against the integrated circuit 14 by the spring member 18.

In the second exemplary embodiment, when the spring member 18 is pressed by the jig 80, and when this pressing is released, the jig 80 is moved in directions toward and away from the mounting face 12A of the substrate 12 with respect to the integrated circuit 14. The radiating member 76 and jig 80 are not moved at side positions SP of the radiating member 76, making it possible for other members to be placed at the side positions SP.

Note that in the second exemplary embodiment, in the example described above the shape of the radiating portions 78 and the internal shape of the jig 80 are the same as each other (circular) when viewed along the arrow A1 direction, however the shapes may differ from each other. In other words, it is sufficient that the pressing portion 82 of the jig 80 is capable of pressing portions of the spring member 18 that jut out from the radiating member 76.

Next, explanation follows regarding a third exemplary embodiment. In the third exemplary embodiment, elements, members and so on similar to those of the first exemplary embodiment are allocated the same reference numerals, and detailed explanation thereof is omitted.

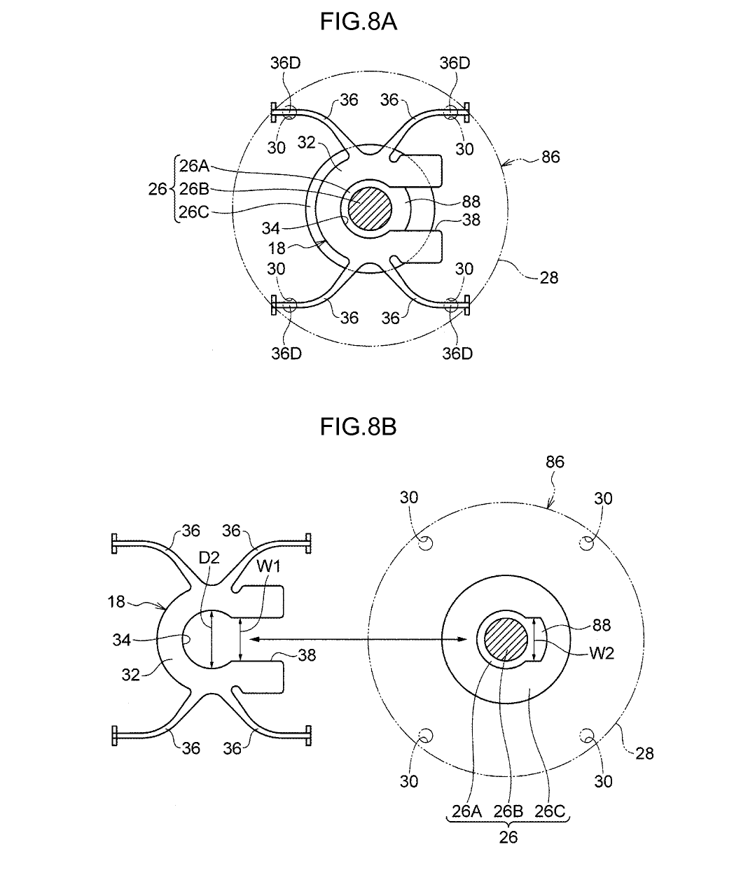

As illustrated in FIG. 8A and FIG. 8B, a radiating member 86 of the third exemplary embodiment is formed with a projection portion 88 where the diameter of the circumferential direction of the seat portion 26A is locally enlarged. A width W2 of the projection portion 88 is similar to the internal width W1 of the opening portion 38 of the spring member 18. As illustrated in FIG. 8A, the position of the projection portion 88 is a position housed in the opening portion 38 in a state in which the spring member 18 is mounted to the radiating member 86, and through holes 30 of the radiating portions 28 are aligned with the fixing portions 36 (pressed portions 36D) of the spring member 18. Relative rotation between the spring member 18 and the radiating member 86 is accordingly suppressed. In the third exemplary embodiment, the projection portion 88 and the opening portion 38 are an example of a rotation suppressing portion.

The component mounting method of the third exemplary embodiment can be performed using a similar routine to that of the component mounting method of the first exemplary embodiment.

In particular, in the third exemplary embodiment, fitting the spring member 18 to the radiating member 86 positions the projection portion 88 in the opening portion 38, suppressing relative rotation between the spring member 18 and the radiating member 86. Namely, as viewed along the arrow A1 direction, the through holes 30 of the radiating portions 28 are aligned with the fixing portions 36 of the spring member 18, and the radiating member 86 and the spring member 18 are suppressed from undergoing relative rotation away from this state. Accordingly, as viewed along the arrow A1 direction, the through holes 30 of the radiating portions 28 are easily maintained in an aligned state with the fixing portions 36 of the spring member 18.

Next, explanation follows regarding a fourth exemplary embodiment. In the fourth exemplary embodiment, elements, members and so on similar to those of the first exemplary embodiment are allocated the same reference numerals, and detailed explanation thereof is omitted.

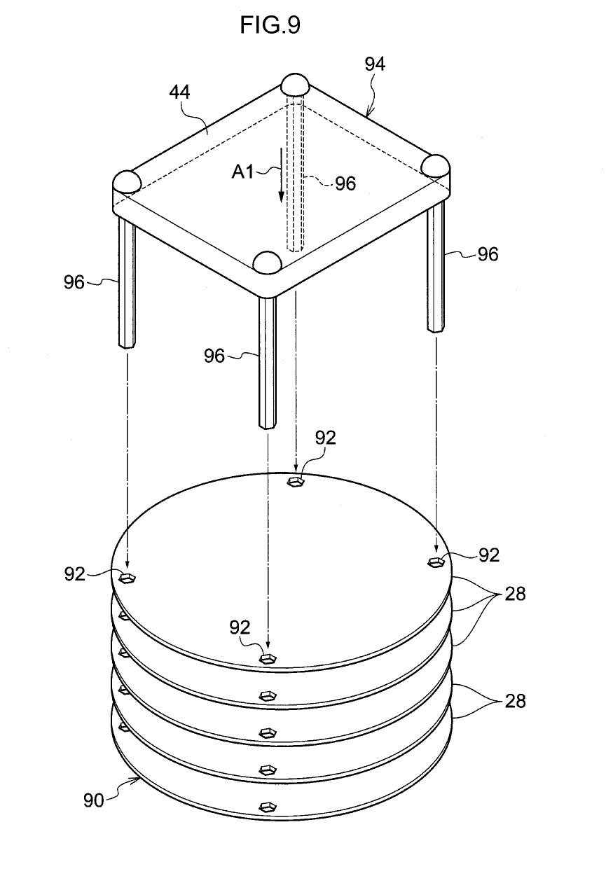

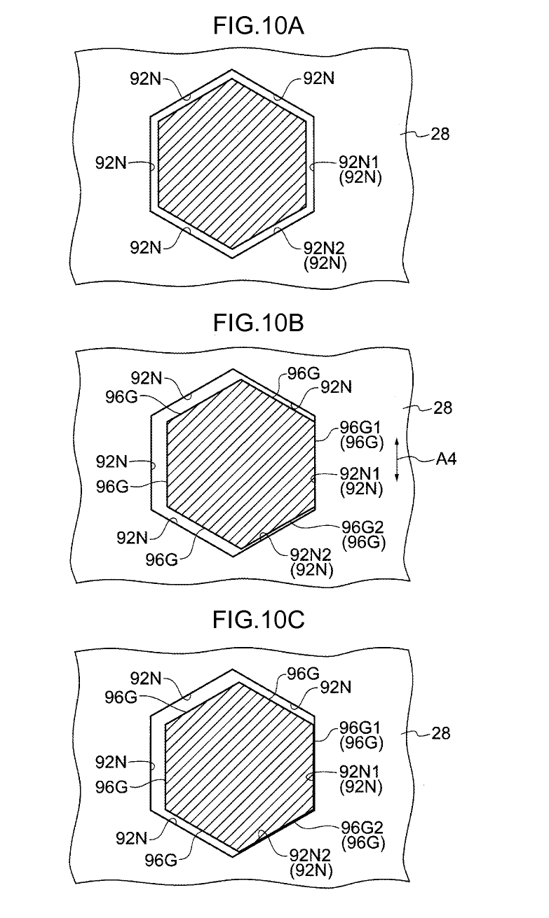

As illustrated in FIG. 9, in the fourth exemplary embodiment, polygonal through holes 92 are formed in a radiating member 90 as viewed along the arrow A1 direction. Press pins 96 of a jig 94 of the fourth exemplary embodiment are formed in polygonal shapes that are slightly smaller than the through holes 92 as viewed along the arrow A1 direction. In the examples illustrated in FIG. 9 and FIG. 10A to FIG. 10C, the through holes 92 and the press pins 96 are formed in regular hexagonal shapes.

The component mounting method of the fourth exemplary embodiment can be performed by a similar routine to the component mounting method of the first exemplary embodiment.

In particular, in the fourth exemplary embodiment, as illustrated in FIG. 10A, a non-contact state can be achieved between respective inner faces 92N of the through holes 92 and respective outer faces 96G of the press pins 96. Moreover, in the fourth exemplary embodiment, as illustrated in FIG. 10B, a specific inner face 92N1 of the respective through holes 92 sometimes contacts a specific outer face 96G1 of the respective press pins 96. Since the through holes 92 and the press pins 96 are formed in the same polygonal shapes as each other, face-to-face contact is achieved between the inner face 92N1 and the outer face 96G1.

When the inner face 92N1 and the outer face 96G1 make face-to-face contact, the direction of relative movement between the press pins 96 and the through holes 92 is limited to a direction along the inner face 92N1 (the arrow A4 direction). Namely, the direction of rattling between the radiating member 90 and the jig 94 can be suppressed to a specific direction.

Moreover, for example as illustrated in FIG. 10C, in addition to the face-to-face contact between the inner face 92N1 and the outer face 96G1, a face-to-face contact state can be achieved between an inner face 92N2 adjacent to the inner face 92N1, and an outer face 96G2 adjacent to the outer face 96G1. In this state, the direction of relative movement between the press pins 96 and the through holes 92 is further limited.

In both the third exemplary embodiment and the fourth exemplary embodiment, when the spring member 18 is pressed by the jig 22, 94, and when this pressing is released, the jig 22, 94 is moved in directions toward and away from the mounting face 12A of the substrate 12 with respect to the integrated circuit 14. Since the radiating member 86, 90 and the jig 22, 94 do not move at the side positions SP of the radiating member 86, 90 it is possible to place other members at the side positions SP (see FIG. 1 and FIG. 6).

The radiating portions 28 of the radiating member 16, 86, 90 of the first, third and fourth exemplary embodiments cover the fixing portions 36 of the spring member 18 as viewed along the arrow A1 direction. However when viewed along the arrow A1 direction, portions of the respective fixing portions 36 can be partially seen through the through holes 30, 92 formed to the radiating portions 28. The fixing portions 36 can be pressed by inserting the press pins 42 of the jig 22, 94 through the through holes 30.

The through holes 30 can be formed such that the fixing portions 36 of the spring member 18 can be seen along the arrow A1 direction even with various radiating members including radiating portions 28 with different external diameters D1. The press pins 42, 96 of a single type of jig 22, 94 can accordingly be inserted into the through holes 30 and press the fixing portions 36 regardless of the size of the radiating portions 28. Namely, a common jig 22, 94 can be achieved.

Similarly, setting the length of the press pins 42, 96 with sufficient length enables a common jig 22, 94 for various radiating members, even for radiating members with a tall overall height.

In the first, third, and fourth exemplary embodiments, the contact portion 24 can be placed in contact with the upper face 14A of the integrated circuit 14 after fitting the spring member 18 to the radiating member 16, 86, 90. Easy operation is enabled since the radiating member 16, 86, 90 and the spring member 18 can be handled as a single unit.

Moreover, the spring member 18 includes the fitting portion 32. Fitting the spring member 18 to the radiating member 16, 86, 90 using the fitting portion 32 enables an easier fitting operation than when the spring member does not include the fitting portion 32.

In the radiating member 76 of the second exemplary embodiment, portions of the fixing portions 36 jut out to the outside of the radiating portions 78 as viewed along the arrow A1 direction. The leading end 82A of the pressing portion 82 of the jig 80 of the second exemplary embodiment presses the fixing portions 36 of the spring member 18. The pressing portion 82 has a circular cylinder shape, with a symmetrical shape around the circumferential direction, such that the circumferential direction orientation does not have to be considered when pressing the fixing portions 36, enabling an easy pressing operation.

In the second exemplary embodiment, setting the internal diameter D3 and the height H1 of the pressing portion 82 (see FIG. 7C) sufficiently large enables a common jig 80 to be used with various radiating members with shapes that can be contained within the pressing portion 82.

In the radiating member 16, 76, 86, 90 of each of the exemplary embodiments, the support column 26 extends out from the contact portion 24 that contacts the integrated circuit 14, and the radiating portions 28, 78 extend out from the support column 26 in a direction orthogonal to the projection direction of the support column 26. Forming the radiating portions 28, 78 to the support column 26 enables the radiating portions 28 to be provided at a position separated from the integrated circuit 14. A structure in which plural of the radiating portions 28, 78 are disposed at intervals to one another can also be achieved.

Each of the exemplary embodiments described above has a structure in which a single jig (the jig 22, the jig 80, or the jig 94) is capable of pressing the plural fixing portions 36. The pressing operation of the fixing portions 36 of the spring member 18 using the jig is accordingly easier than when plural jigs are employed.

In each of the exemplary embodiments, the pressed portions 36D of the fixing portions 36 of the spring member 18 are positioned within the single flat plane P1. Moreover, in the first, the third, and the fourth exemplary embodiments, the leading ends 42A of the press pins 42 are positioned within the single flat plane P2. In the second exemplary embodiment, the entire range of the leading end 82A of the pressing portion 82 is positioned within the single flat plane P3. A near-uniform pressing force against the fixing portions 36 by the leading ends of the press pins 42 is accordingly possible.

The housing hole 34 of the spring member 18 has the internal diameter D2 that is slightly larger than the external diameter D1 of the seat portion 26A of the support column 26, thereby enabling rattling to be suppressed in the fitted state of the spring member 18 to the radiating member 16.

The spring member 18 is provided with plural of the fixing portions 36. The spring member 18 can accordingly be fixed to the substrate 12 more firmly and stably than when a spring member with only a single fixing portion 36 is employed.

The fixing portions of the spring member may have a structure fixed to the mounting face 12A, rather than the back face 12B, of the substrate 12 using solder or adhesive.

The plural fixing portions 36 extend out from the fitting portion 32 in a radiating shape. Since the fixing portions 36 have little irregularity around the circumferential direction of the fitting portion 32, the force with which the spring member 18 pushes the radiating member 16 also has little irregularity.

Electronic components are not limited to the integrated circuit 14 described above, and may, for example, include various devices attached to the substrate 12. In particular, even when the integrated circuit 14 is an integrated circuit formed with an uneven upper face 14A, the radiating member 16 can be disposed in contact with the upper face 14A since the radiating member 16 is pushed against the upper face 14A of the integrated circuit 14 from the opposite side to the substrate 12 in each of the exemplary embodiments described above.

The mounting component is not limited to the radiating member 16 described above, and may be any component disposed in contact with an electronic component, such as a spacer or cover member that separates the electronic component from peripheral members (that maintains a non-contact state).

Explanation has been given regarding exemplary embodiments of technology disclosed herein, however the technology disclosed herein is not limited thereto, and it goes without saying that various modifications may be implemented within a range not departing from the spirit of the technology disclosed herein.

According to the technology disclosed herein, space for a mounting operation of a mounting component is not required at positions to the side of a mounting component on a substrate, and other components can be placed at positions to the side of the mounting component.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

All cited documents, patent applications and technical standards mentioned in the present specification are incorporated by reference in the present specification to the same extent as if the individual cited documents, patent applications and technical standards were specifically and individually incorporated by reference in the present specification.

What is claimed is:

1. A component mounting method, comprising:
placing a mounting component in contact with, and on top of, an electronic component on a substrate;
pressing a spring member against the mounting component using a jig such that the mounting component is pushed against the electronic component by the spring member, and fixing the spring member to the substrate; and
removing the jig in a direction heading away from a mounting face of the substrate after the spring member has been fixed to the substrate.

2. The component mounting method of claim 1, wherein:
the spring member includes a plurality of fixing portions for fixing to the substrate; and
the plurality of fixing portions are pressed when the spring member is pressed by the jig.

3. The component mounting method of claim 2, wherein:
the mounting component is formed with through holes through which the fixing portions can be seen from the mounting face side of the substrate; and
pressing portions of the jig are inserted into the through holes and press the fixing portions.

4. The component mounting method of claim 3, wherein the through holes and the pressing portions have polygonal shapes as viewed from the mounting face side.

5. The component mounting method of claim 2, wherein:
the fixing portions include jutting-out portions that jut out to an outer side of the mounting component as viewed from the mounting face side; and
the jutting-out portions of the fixing portions are pressed when the spring member is pressed by the jig.

6. The component mounting method of claim 2, wherein the plurality of fixing portions are pressed by a single jig.

7. The component mounting method of claim 6, wherein:
portions of the plurality of fixing portions that are pressed by the jig are positioned within a single flat plane parallel to the substrate; and
portions of the jig that press the fixing portions press the fixing portions in parallel to the substrate.

8. The component mounting method of claim 1, wherein the mounting component is placed in contact with, and on top of, the electronic component after the spring member has been fitted to the mounting component.

9. The component mounting method of claim 2, wherein:
the spring member includes a fitting portion that is fitted to the mounting component; and
the plurality of fixing portions extend out from the fitting portion in radiating directions.

10. The component mounting method of claim 9, wherein:
the mounting component includes a support column portion extending from a portion of contact with the electronic component;
the spring member includes a housing hole that houses the support column portion; and
the support column portion and the housing hole include a rotation suppressing portion that suppresses rotation of the support column portion with respect to the housing hole.

11. The component mounting method of claim 1, wherein the spring member is fixed to the substrate while the spring member is pressed by the jig and the spring member is in a flexed state.

12. The component mounting method of claim 2, wherein fixing holes are formed in the substrate into which the fixing portions are to be inserted, and the fixing portions are inserted into the fixing holes and prevented from coming out.

13. A mounting component, comprising:
a contact portion that contacts an electronic component on a substrate;
a support column portion that projects outward from the contact portion;
an extension portion that extends outward from the support column portion in a direction intersecting with a direction of projection of the support column portion; and
a through hole that penetrates the extension portion.

14. The mounting component of claim 13, wherein the through hole has a polygonal shape.
